(19) United States
(12) Patent Application Publication
(10) Pub. No.: US 2024/0234456 A1
(43) Pub. Date: Jul. 11, 2024

(54) OPTICAL DEVICES INCLUDING GLASS COVER WITH PATTERNED ANTIREFLECTIVE COATING

(71) Applicant: SEMICONDUCTOR COMPONENTS INDUSTRIES, LLC, Phoenix, AZ (US)

(72) Inventors: Yu-Te HSIEH, Taoyuan City (TW); Yusheng LIN, Phoenix, AZ (US)

(73) Assignee: SEMICONDUCTOR COMPONENTS INDUSTRIES, LLC, Phoenix, AZ (US)

(21) Appl. No.: 18/153,267

(22) Filed: Jan. 11, 2023

(51) Int. Cl. H01L 27/146

(52) U.S. Cl. CPC H01L 27/14623; H01L 27/14618; H01L 27/14685

(57) ABSTRACT

In a general aspect, a package includes a semiconductor die including an optical device having an optically active area on a first side of the semiconductor die. The package also includes a glass cover having an antireflective coating disposed on a central portion of a first side of the glass cover. A perimeter portion of the first side of the glass cover excludes the antireflective coating. The package further includes an adhesive resin coupling the perimeter portion of the first side of the glass cover with the first side of the semiconductor die, such that the glass cover is disposed above and spaced from the optically active area.

### TECHNICAL FIELD

This description relates to semiconductor optical devices, such as image sensors.

### BACKGROUND

Digital image sensors (e.g., a complementary metal-oxide-semiconductor image sensor (CIS) or a charge-coupled device (CCD)), or other semiconductor optical devices, are typically packaged in an integrated circuit (IC) package (i.e., a ceramic ball grid array package (CBGA) or a plastic ball grid array (PBGA) package along with an antireflective (AR) coated glass cover placed over a semiconductor die including the optical device, e.g., an image sensor. Current implementations have certain drawbacks, however. For instance, curing of an adhesive used to couple the glass cover to the semiconductor die can be time consuming, and/or difficult to achieve sufficient curing. Also, heating caused during a curing process can result in misalignment of the glass cover, tilt of the glass cover, and/or adversely affect bond line thickness of the adhesive resin, which can all negatively affect optical properties of the device.

### SUMMARY

In a general aspect, a package includes a semiconductor die including an optical device having an optically active area on a first side of the semiconductor die. The package also includes a glass cover having an antireflective coating disposed on a central portion of a first side of the glass cover. A perimeter portion of the first side of the glass cover excludes the antireflective coating. The package further includes an adhesive resin coupling the perimeter portion of the first side of the glass cover with the first side of the semiconductor die, such that the glass cover is disposed above and spaced from the optically active area.

Implementations can include one or more of the following features, or any combination thereof. For example, the antireflective coating can be disposed on a central portion of a second side of the glass cover that is opposite the first side of the glass cover. A perimeter portion of the second side of the glass cover can exclude the antireflective coating. The second side of the glass cover can be exposed outside the package.

The glass cover, the adhesive resin and the semiconductor die can define a hermetically sealed cavity. The optically active area of the semiconductor die can be disposed within the hermetically sealed cavity.

The adhesive resin is an ultraviolet light cured adhesive resin.

The package can further include a substrate coupled with a second side of the semiconductor die that is opposite the first side of the semiconductor die. The package can include at least one wire bond electrically coupling the substrate with the semiconductor die. The package can include a molding compound disposed on a portion of the substrate. The molding compound can encapsulate the at least one wire bond. The at least one wire bond and the molding compound can be disposed outside a hermetically sealed cavity defined by the glass cover, the adhesive resin and the semiconductor die. The substrate includes a ball-grid-array (BGA) substrate.

In another general aspect, a package includes a semiconductor die including an image sensor having an optically active area on a first side of the semiconductor die. The package also includes a substrate coupled with a second side of the semiconductor die that is opposite the first side of the semiconductor die. The package further includes a glass cover having an antireflective coating disposed on a central portion of a first side of the glass cover, and on a central portion of a second side of the glass cover that is opposite the first side of the glass cover. A perimeter portion of the first side of the glass cover and a perimeter portion of the second side of the glass cover exclude the antireflective coating. The package also includes an adhesive resin coupling the perimeter portion of the first side of the glass cover with the first side of the semiconductor die. The glass cover is disposed above and spaced from the optically active area.

Implementations can include one or more of the following features, or any combination thereof. For example, the glass cover, the adhesive resin, and the semiconductor die can define a hermetically sealed cavity. The optically active area of the semiconductor die can be disposed within the hermetically sealed cavity.

The adhesive resin can be an ultraviolet light cured adhesive resin.

The package can include at least one wire bond electrically coupling the substrate with the semiconductor die. The package can include a molding compound disposed on a portion of the substrate. The molding compound can encapsulate the at least one wire bond. The at least one wire bond and the molding compound can be disposed outside a hermetically sealed cavity defined by the glass cover, the adhesive resin and the semiconductor die.

The substrate can include a ball-grid-array (BGA) substrate.

The second side of the glass cover can be exposed outside the package.

The image sensor includes a complementary metal-oxide semiconductor (CMSO) image sensor.

In another general aspect, a method includes coating a first side of a glass cover for an optical device and a second side of the glass cover with photoresist. The second side of the glass cover is opposite the first side of the glass cover. The method further includes exposing and developing the photoresist such that the photoresist is removed from respective central portions of the first side of the glass cover and the second side of the glass cover. The photoresist remains on respective perimeter portions of the first side of the glass cover and the second side of the glass cover. The method also includes coating the first side of the glass cover and the second side of the glass cover with a broadband antireflective (BBAR) coating. The method still further includes stripping the photoresist from the respective perimeter portions. The stripping removes the photoresist and the BBAR coating from the respective perimeter portions.

Implementations can include one or more of the following features, or any combination thereof. For example, the method can include coupling, with an adhesive resin, the respective perimeter portion of the first side of the glass cover with a semiconductor die including the optical device. The glass cover can be disposed above and spaced from an optically active area of the optical device. The method can include curing the adhesive resin with ultraviolet light.

Coating the first side of the glass cover and the second side of the glass cover with the BBAR coating can include coating the first side of the glass cover and the second side of the glass cover using evaporative coating.

The BBAR coating can have a thickness between 1 nanometer (nm) and 100 nm.

The details of one or more implementations are set forth in the accompanying drawings and the description below. Other features will be apparent from the description and drawings, and from the claims.

### BRIEF DESCRIPTION OF THE DRAWINGS

FIG. 1 is a diagram illustrating an example optical device package.

FIG. 2 is a diagram illustrating a side, cross-sectional view of an example optical device assembly that can be included in the package of FIG. 1.

FIG. 3 is a diagram illustrating a side, cross-sectional view of another example optical device assembly that can be included in the package of FIG. 1.

FIG. 4 is a diagram illustrating a side, cross-sectional view of an example optical device package that can include the assembly of FIG. 2, or the assembly of FIG. 3.

FIG. 5 is a diagram illustrating a process flow for producing a glass cover for an optical device assembly or optical device package.

In the drawings, which may not necessarily be to scale, reference numbers for like or similar elements may not be shown for each of those elements. Also, reference numbers from one view of a given implementation may not be repeated in the related views. Further, in some instances, for purposes of comparing different views, reference numbers from one view of given implementation may be repeated in other views but may not be specifically discussed with respect to each view.

### DETAILED DESCRIPTION

This disclosure is directed to optical devices, such as packaged optical devices, and associated methods of manufacture, which can overcome at least some of the drawbacks of previous approaches. For instance, in prior approaches, AR coated glass covers, while desirably improving transmission of visible and infrared light, significantly inhibit transmission of ultraviolet (UV) light, e.g., blocking up to 90% of UV light. Accordingly, curing an adhesive resin used to couple an AR coated glass cover with a semiconductor optical device can require long cure times, and/or can result in insufficient curing of the adhesive resin. Furthermore, prior approaches can include the use of high-intensity UV light for adhesive resin curing, which can cause excessive heating resulting in cover misalignment, cover tilt, and/or issues controlling a bond line thickness of the adhesive resin and associate spacing between the glass cover and an underlying optical device.

The approaches described herein include the use of a glass cover having a patterned antireflective (AR) coating, e.g., a broadband AR coating (BBAR) coating. For instance, the AR coating can be patterned such that the AR coating is included in a central portion of the glass cover and excluded from a perimeter portion of the glass cover. In example implementations, the central portion can be bounded by the perimeter portion. That is, the perimeter portion can at least partially surround, or fully surround the central portion.

The AR coated central portion can improve transmission of visible light and infrared light to an optically active portion of a semiconductor optical device, such as an image sensor device. The image sensor device can be, for example, a complementary metal-oxide semiconductor (CMOS) image sensor, a charge-coupled device (CCD), etc. Further, by excluding the AR coating from the perimeter portion of the glass cover, transmission of the ultraviolet (UV) light through the perimeter portion for curing an adhesive resin can be increased by 2 to 5 times that of prior approaches.

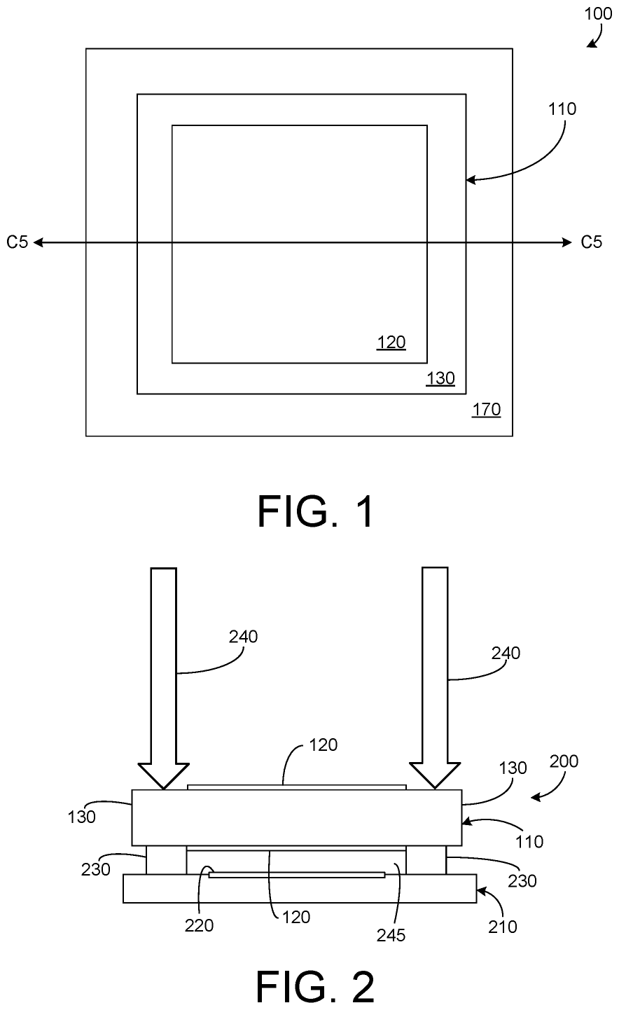

FIG. 1 is a diagram illustrating an example optical device package 100. As shown in FIG. 1, the optical device package 100 includes a glass cover 110 and a molding compound 170. In the optical device package 100, the glass cover 110 can be coupled to a semiconductor die including an optical device, such as in the examples of FIGS. 2-4. The molding compound 170 can encapsulate portions of the optical device package 100. For instance, the molding compound 170 can encapsulate one or more wire bonds. In some implementations, the molding compound 170 can be disposed on a substrate and can also encapsulate, at least in part, the semiconductor die of the optical device package 100.

In this example, the glass cover 110 includes a patterned AR coating 120, e.g., a BBAR coating, that is disposed on a central portion of an outward facing side (surface) of the glass cover 110. In some implementations, an inward facing side (surface) that is opposite the outward facing side of the glass cover 110 can also have a patterned AR coating that mirrors the patterned AR coating 120 shown in FIG. 1. The glass cover 110, on the outward facing side, also includes a perimeter portion 130 that excludes the patterned AR coating 120, and bounds (e.g., surrounds) the AR coated central portion. In this example, the inward facing side of the glass cover 110 can also include a perimeter portion excluding the AR coating that mirrors the perimeter portion 130 on the outward facing side of the glass cover 110 shown in FIG. 1.

In this example, adhesive resin used to couple the glass cover 110 with the semiconductor die can be cured with UV light that is transmitted through the perimeter portion 130 on the outward facing side of the glass cover 110 to the perimeter portion of the inward facing side of the glass cover 110. As the perimeter portions of the glass cover 110 exclude the patterned AR coating 120, UV light can be efficiently transmitted through the perimeter portion 130 to cure underlying adhesive resin, e.g., to cure a bond line of the adhesive resin disposed around the perimeter of the glass cover 110 below the perimeter portion 130. That is, the perimeter portion on the inward facing side of the glass cover 110 can be coupled to a semiconductor die of the optical device package 100 with the UV cured resin.

FIG. 1 also includes a section line CS-CS. In this example, the section line CS-CS corresponds with side, cross-sectional views shown in FIGS. 2-4.

FIG. 2 is a diagram illustrating a side, cross-sectional view of an example optical device assembly 200 that can be included in the optical device package 100 of FIG. 1. Accordingly, the optical device assembly 200 will be described with further reference to FIG. 1. The cross-sectional view of the optical device assembly 200 shown in FIG. 2 is along the section line CS-CS of FIG. 1, though the optical device assembly 200 does not include the molding compound 170, bond wires, or an underlying substrate, such as described with respect to the optical device package 100 of FIG. 1. Also, for purposes of clarity and illustration, the view of the optical device assembly 200 in FIG. 2 illustrates structure of the optical device assembly 200 along the section line CS-CS. That is, structure of the optical device assembly 200 that would be behind the view of FIG. 2 (e.g., into the page) is not shown.

In this example, the optical device assembly 200 includes the glass cover 110. As can be seen in FIG. 2, the glass cover 110 has the patterned AR coating 120 disposed on both a central portion of an upper (outward facing) side and a corresponding central portion of a lower (inward facing) side. The perimeter portion 130 of the glass cover 110 excludes the patterned AR coating 120. That is, the patterned AR coating 120 is not disposed on the upper side (surface) or the lower side (surface) of the glass cover 110 in the perimeter portion 130.

The optical device assembly 200 further includes a semiconductor die 210 that includes an optical device, such as an image sensor. For instance, the semiconductor die 210 includes an optically active area 220 that is disposed below the central portion of the glass cover 110 including the patterned AR coating 120. The glass cover 110 is coupled to the semiconductor die 210 with an adhesive resin 230. That is, in this example, the adhesive resin 230 couples the glass cover 110 to the semiconductor die 210 along the perimeter portion 130, such that the glass cover 110 is disposed above, and spaced from the optically active area 220. For instance, in some implementations, a bond line of the adhesive resin 230 can be formed, e.g., printed, etc., on the semiconductor die 210, and the glass cover 110 can be placed on the adhesive resin 230 as shown in FIG. 2. In other implementations, a bond line of the adhesive resin 230 can be formed on the perimeter portion 130, and the glass cover 110 and adhesive resin 230 can be placed on the semiconductor die 210 as shown in FIG. 2.

As shown in FIG. 2, after the adhesive resin 230 and the glass cover 110 are in place on the semiconductor die 210, UV light 240 can be applied to the optical device assembly 200. The UV light 240 will be efficiently transmitted through the perimeter portion 130 of the glass cover 110 to cure the adhesive resin 230, while the patterned AR coating 120 will block most of the UV light 240 from being transmitted through the central portion of the glass cover 110. Accordingly, lower intensity UV light can be used for curing the adhesive resin 230 than UV light used in prior approaches, and the associated drawbacks can be avoided. In this example, the semiconductor die 210, the adhesive resin 230 and the glass cover 110 define a hermetically sealed cavity 245, in which the optically active area 220 of the semiconductor die 210 is contained.

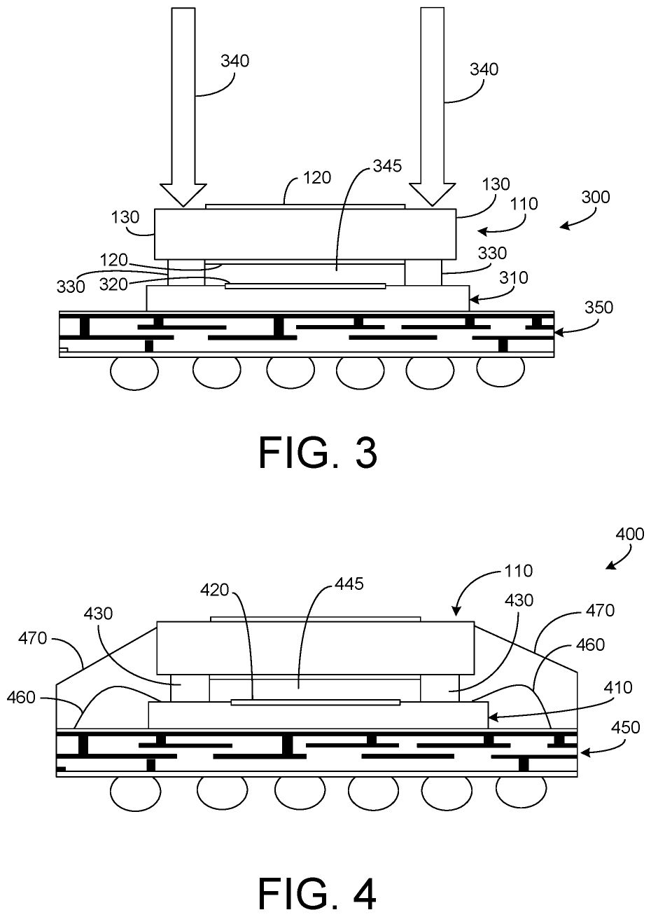

FIG. 3 is a diagram illustrating a side, cross-sectional view of another example optical device assembly 300 that can be included in the optical device package 100 of FIG. 1. Accordingly, the optical device assembly 300 will be described with further reference to FIG. 1. As with the example of FIG. 2, the cross-sectional view of the optical device assembly 300 shown in FIG. 3 is along the section line CS-CS of FIG. 1, though the optical device assembly 300 does not include the molding compound 170, or bond wires, such as described with respect to the optical device package 100 of FIG. 1. Also, for purposes of clarity and illustration, as with the example of FIG. 2, the view of the optical device assembly 300 in FIG. 3 illustrates structure of the optical device assembly 300 along the section line CS-CS. That is, structure of the optical device assembly 300 that would be behind the view of FIG. 3 (e.g., into the page) is not shown.

In this example, the optical device assembly 300 includes the glass cover 110. As can be seen in FIG. 3, the glass cover 110 has the patterned AR coating 120 disposed on both a central portion of an upper (outward facing) side and a corresponding central portion of a lower (inward facing) side. The perimeter portion 130 of the glass cover 110 excludes the patterned AR coating 120. That is, the patterned AR coating 120 is not disposed on the upper side (surface) or the lower side (surface) of the glass cover 110 in the perimeter portion 130.

The optical device assembly 300 further includes a semiconductor die 310 that includes an optical device, such as an image sensor. For instance, the semiconductor die 310 includes an optically active area 320 that is disposed below the central portion of the glass cover 110 including the patterned AR coating 120. The semiconductor die 310 is coupled to a substrate 350. In this example, the substrate 350 is a ball-grid-array substrate, such as a ceramic BGA or a plastic BGA.

As with the optical device assembly 200, the glass cover 110 is coupled to the semiconductor die 310 with an adhesive resin 330. That is, the adhesive resin 330 couples the glass cover 110 to the semiconductor die 310 along the perimeter portion 130, such that the glass cover 110 is disposed above, and spaced from the optically active area 320. For instance, in some implementations, a bond line of the adhesive resin 330 can be formed, e.g., printed, etc., on the semiconductor die 310, and the glass cover 110 can be placed on the adhesive resin 330 as shown in FIG. 3. In other implementations, a bond line of the adhesive resin 330 can be formed on the perimeter portion 130, and the glass cover 110 and adhesive resin 330 can be placed on the semiconductor die 310 as shown in FIG. 3.

As shown in FIG. 3, after the adhesive resin 330 and the glass cover 110 are in place on the semiconductor die 310, UV light 340 can be applied to the optical device assembly 300. The UV light 340 will be efficiently transmitted through the perimeter portion 130 of the glass cover 110 to cure the adhesive resin 330, while the patterned AR coating 120 will block most of the UV light 340 from being transmitted through the central portion of the glass cover 110. Accordingly, lower intensity UV light can be used for curing the adhesive resin 330 than UV light used in prior approaches, and the associated drawbacks can be avoided. In this example, the semiconductor die 310, the adhesive resin 330 and the glass cover 110 define a hermetically sealed cavity 345, in which the optically active area 320 of the semiconductor die 310 is contained.

FIG. 4 is a diagram illustrating a side, cross-sectional view of an example optical device package 400 that can include the assembly of FIG. 2 or the assembly of FIG. 3. The optical device package 400 can be an implementation of the optical device package 100 of FIG. 1. For purposes of illustration, the optical device package 400 will be described with further reference to, at least, FIGS. 1 and 3. As with the example of FIG. 3, the cross-sectional view of the optical device package 400 shown in FIG. 4 is along the section line CS-CS of FIG. 1. Also, for purposes of clarity and illustration, as with the example of FIG. 3, the view of the optical device package 400 in FIG. 4 illustrates structure of the optical device package 400 along the section line CS-CS. That is, structure of the optical device package 400 that would be behind the view of FIG. 4 (e.g., into the page) is not shown.

In this example, the optical device package 400 includes the glass cover 110. The optical device package 400 further includes a semiconductor die 410 that includes an optical device, such as an image sensor. For instance, the semiconductor die 410 includes an optically active area 420 that is disposed below the central portion of the glass cover 110. The semiconductor die 410 is coupled to a substrate 450, e.g., using a die attach adhesive. In this example, the substrate 450 is a ball-grid-array substrate, such as a ceramic BGA or a plastic BGA.

As with the optical device assembly 300, the glass cover 110 in the optical device package 400 is coupled to the semiconductor die 410 with an adhesive resin 430. That is, the adhesive resin 430 couples the glass cover 110 to the semiconductor die 410 along a perimeter portion of the glass cover 110, such that the glass cover 110 is disposed above, and spaced from the optically active area 420. In this example, the semiconductor die 410, the adhesive resin 430 and the glass cover 110 define a hermetically sealed cavity 445, in which the optically active area 420 of the semiconductor die 410 is contained.

The optical device package 400 further includes wire bonds 460 that electrically couple the substrate 450 with the semiconductor die 410, e.g., to electrically connect solder balls of the substrate 450 with the semiconductor die 410 via the substrate 450. In this example, the optical device package 400 further includes a molding compound 470 that is disposed on the substrate 450. As shown in FIG. 4, the molding compound 470 encapsulates the wire bonds 460 and encapsulates, at least in part, the semiconductor die 410. The molding compound 470 is also disposed on side surfaces of the adhesive resin 430 and the glass cover 110, which can provide structural integrity for the optical device package 400.

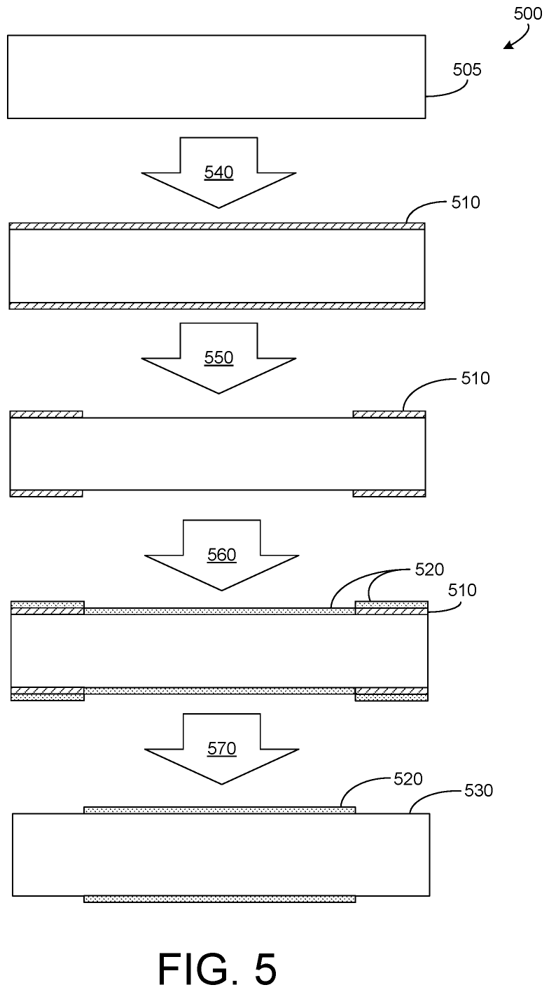

FIG. 5 is a diagram illustrating a process 500 for producing a glass cover for an optical device assembly or optical device package, such as those described herein. While the process 500 is illustrated for a single glass cover, in some implementations, the process 500 can be implemented to concurrently produce a plurality of glass covers, such as from a larger glass plate. In some implementations, individual glass covers can be singulated from the glass plate prior to attachment to respective semiconductor die with adhesive resin. In other implementations, the glass plate can be coupled a semiconductor wafer, where the plurality glass covers defined on the glass plate are aligned with, and coupled to, respective semiconductor die on the wafer, e.g., using UV light cured adhesive resin. In such implementations, the individual glass covers, and the corresponding semiconductor die can be singulated concurrently. The views shown in FIG. 5 are side, cross-sectional views along a section line that is consistent with the section line CS-CS of FIG. 1 for the glass cover 110.

As shown in FIG. 5, a glass cover 505 is provided. Operation 540 of the process 500 includes applying photoresist 510 to the glass cover 505. As shown in FIG. 5, the photoresist 510 can be applied to an upper side (surface) and a lower side (surface) of the glass cover 505. The photoresist 510 can be applied using spin coating and bake operations, where the bake operations are used to solidify the photoresist 510 by evaporating one or more solvents from the photoresist coating.

Operation 550 of the process 500 includes exposing and developing the photoresist 510, e.g., using a photo mask and UV light. As shown in FIG. 5, the operation 550 results in respective central portions of the upper side and the lower side of the glass cover 505 being exposed through the photoresist 510. That is, respective photoresist masks are formed from the photoresist 510 that remains on the upper side and the lower side of the glass cover 505 as a result of the operation 550.

Operation 560 of the process 500 includes forming an AR coating layer 520 on the upper side and the lower side of the glass cover 505. As shown in FIG. 5, the AR coating layer 520 is formed on the exposed central portions of the upper side and the lower side of the glass cover 505, as well as on the photoresist masks. In some implementations, the AR coating layer 520 can be formed using evaporative coating. The AR coating layer 520 can include, for example, titanium dioxide and/or silicon dioxide.

Operation 570 of the process 500 includes performing a photoresist strip process, which removes the photoresist masks formed by the operation 550 and lifts off the portions of the AR coating layer 520 disposed on the photoresist masks by the operation 560. That is, the operation 570 exposes perimeter portions 530 upper side and lower side of the glass cover 505, which can then be used to transmit UV light for curing an adhesive resin used to couple the glass cover 505 with a corresponding semiconductor die of an optical device assembly or optical device package, such as in the examples described herein.

While certain features of the described implementations have been illustrated as described herein, many modifications, substitutions, changes, and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

It will be understood that, in the foregoing description, when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in this specification, a singular form may, unless indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising,” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. Ranges may be expressed herein as from “about” one particular value, and/or to “about” another particular value. When such a range is expressed, an aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Some implementations may be implemented using various semiconductor processing and/or packaging techniques. Some implementations may be implemented using various types of semiconductor processing techniques associated with semiconductor substrates including, but not limited to, for example, silicon (Si), gallium arsenide (GaAs), gallium nitride (GaN), silicon carbide (SiC) and/or so forth.

What is claimed is:

1. A package comprising:
a semiconductor die including an optical device having an optically active area on a first side of the semiconductor die;
a glass cover having an antireflective coating disposed on a central portion of a first side of the glass cover, a perimeter portion of the first side of the glass cover excluding the antireflective coating; and
an adhesive resin coupling the perimeter portion of the first side of the glass cover with the first side of the semiconductor die, such that the glass cover is disposed above and spaced from the optically active area.

2. The package of claim 1, wherein the antireflective coating is disposed on a central portion of a second side of the glass cover that is opposite the first side of the glass cover, a perimeter portion of the second side of the glass cover excluding the antireflective coating, the second side of the glass cover being exposed outside the package.

3. The package of claim 1, wherein the glass cover, the adhesive resin and the semiconductor die define a hermetically sealed cavity, the optically active area of the semiconductor die being disposed within the hermetically sealed cavity.

4. The package of claim 1, wherein the adhesive resin is an ultraviolet light cured adhesive resin.

5. The package of claim 1, further comprising:
a substrate coupled with a second side of the semiconductor die that is opposite the first side of the semiconductor die;
at least one wire bond electrically coupling the substrate with the semiconductor die; and
a molding compound disposed on a portion of the substrate, the molding compound encapsulating the at least one wire bond.

6. The package of claim 5, wherein the at least one wire bond and the molding compound are disposed outside a hermetically sealed cavity defined by the glass cover, the adhesive resin and the semiconductor die.

7. The package of claim 5, wherein the substrate includes a ball-grid-array (BGA) substrate.

8. A package comprising:
a semiconductor die including an image sensor having an optically active area on a first side of the semiconductor die;
a substrate coupled with a second side of the semiconductor die that is opposite the first side of the semiconductor die;
a glass cover having an antireflective coating disposed on:
a central portion of a first side of the glass cover; and
a central portion of a second side of the glass cover that is opposite the first side of the glass cover,
a perimeter portion of the first side of the glass cover and a perimeter portion of the second side of the glass cover excluding the antireflective coating; and
an adhesive resin coupling the perimeter portion of the first side of the glass cover with the first side of the semiconductor die, such that the glass cover is disposed above and spaced from the optically active area.

9. The package of claim 8, wherein the glass cover, the adhesive resin, and the semiconductor die define a hermetically sealed cavity, the optically active area of the semiconductor die being disposed within the hermetically sealed cavity.

10. The package of claim 8, wherein the adhesive resin is an ultraviolet light cured adhesive resin.

11. The package of claim 8, further comprising:
at least one wire bond electrically coupling the substrate with the semiconductor die; and
a molding compound disposed on a portion of the substrate, the molding compound encapsulating the at least one wire bond.

12. The package of claim 11, wherein the at least one wire bond and the molding compound are disposed outside a hermetically sealed cavity defined by the glass cover, the adhesive resin and the semiconductor die.

13. The package of claim 8, wherein the substrate includes a ball-grid-array (BGA) substrate.

14. The package of claim 8, wherein the second side of the glass cover is exposed outside the package.

15. The package of claim 8, wherein the image sensor includes a complementary metal-oxide semiconductor (CMOS) image sensor.

16. A method comprising:
coating with photoresist:
a first side of a glass cover for an optical device; and
a second side of the glass cover, the second side of the glass cover being opposite the first side of the glass cover;
exposing and developing the photoresist such that:
the photoresist is removed from respective central portions of the first side of the glass cover and the second side of the glass cover; and
the photoresist remains on respective perimeter portions of the first side of the glass cover and the second side of the glass cover;
coating the first side of the glass cover and the second side of the glass cover with a broadband antireflective (BBAR) coating;
stripping the photoresist from the respective perimeter portions, the stripping removing the photoresist and the BBAR coating from the respective perimeter portions.

17. The method of claim 16, further comprising:
coupling, with an adhesive resin, the respective perimeter portion of the first side of the glass cover with a semiconductor die including the optical device, the glass cover being disposed above and spaced from an optically active area of the optical device; and
curing the adhesive resin with ultraviolet light.

18. The method of claim 16, wherein coating the first side of the glass cover and the second side of the glass cover with the BBAR coating includes coating the first side of the glass cover and the second side of the glass cover using evaporative coating.

19. The method of claim 16, wherein the BBAR coating has a thickness between 1 nanometer (nm) and 100 nm.
